(19) United States
(12) Patent Application Publication
(10) Pub. No.: US 2025/0238364 A1
(43) Pub. Date: Jul. 24, 2025

(54) STORAGE CONTROLLER, MEMORY SYSTEM INCLUDING THE SAME, AND OPERATING METHOD OF THE MEMORY SYSTEM

(71) Applicant: SAMSUNG ELECTRONICS CO., LTD., Suwon-si (KR)

(72) Inventors: Donghyuk Shin, Suwon-si (KR); Sejong Kim, Suwon-si (KR); Joonhyuck Shin, Suwon-si (KR); Junchul Choi, Suwon-si (KR); Donghoon Ham, Suwon-si (KR); Jinwoo Hong, Suwon-Si (KR)

(21) Appl. No.: 18/986,416

(22) Filed: Dec. 18, 2024

(30) Foreign Application Priority Data
Jan. 24, 2024 (KR) 10-2024-0011181

(51) Int. Cl. G06F 12/02

(52) U.S. Cl. CPC G06F 12/0246; G06F 2212/7203

(57) ABSTRACT

A memory system includes a storage controller for transmitting a read command to a memory device including a plurality of planes, the memory system including a command generation module configured to generate a first read command signal including an address signal set for each of the plurality of planes or a second read command signal including an address signal applied collectively to the plurality of planes, a command selection module configured to determine either the first read command signal or the second read command signal as the read command, and a memory controller configured to transmit the determined read command to the memory device.

### CROSS-REFERENCE TO RELATED APPLICATION

This application claims priority to Korean Patent Application No. 10-2024-0011181, filed in the Korean Intellectual Property Office on Jan. 24, 2024, the disclosure of which is incorporated by reference herein in its entirety.

### BACKGROUND

Recently developed memory devices are configured to include a plurality of storage areas. For example, a memory device may include a plurality of planes. The plurality of planes included in the memory device may have different read voltage levels. However, a read command is generated based on an address signal level for one of the plurality of planes, and the address signal level is corrected while a read operation is performed on each of the planes.

Accordingly, when a read operation is performed on a plurality of planes included in an existing memory device, the power and time consumed to correct an address signal level may increase.

### SUMMARY

In general, in some aspects, the present disclosure is directed toward a memory system that generates a command signal including an address signal for each of a plurality of planes included in a memory device, thereby reducing power consumed by the memory device.

According to some implementations, the present disclosure is directed to a memory system that includes a storage controller for transmitting a read command to a memory device including a plurality of planes, the memory system including a command generation module configured to generate a first read command signal including an address signal set for each of the plurality of planes, or a second read command signal including an address signal applied collectively to the plurality of planes, a command selection module configured to determine either the first read command signal or the second read command signal as the read command, and a memory controller configured to transmit the determined read command to the memory device.

In some implementations, the command generation module may be further configured to generate the first read command signal when read levels required for correction of the plurality of planes are different.

According to some implementations, the present disclosure is directed to an operating method of a memory system for generating a read command for a memory device including a plurality of planes, the operating method including determining a deviation in read levels of the plurality of planes, determining, based on a result of the determining, either a first read command signal or a second read command signal as the read command, and transmitting the determined read command to the memory device.

In some implementations, the determining of either the first read command signal or the second read command signal as the read command may include generating the first read command signal when read levels required for correction of the plurality of planes are different.

According to some implementations, the present disclosure is directed to a storage controller of a memory system for transmitting a read command to a memory device including a plurality of planes, the storage controller including a command generation module configured to generate a first read command signal including an address signal set for each of the plurality of planes, or a second read command signal including an address signal applied collectively to the plurality of planes, a command selection module configured to determine either the first read command signal or the second read command signal as the read command, and a memory controller configured to transmit the determined read command to the memory device.

In some implementations, the command generation module may be further configured to generate the first read command signal when read levels required for correction of the plurality of planes are different.

### BRIEF DESCRIPTION OF THE DRAWINGS

Example implementations will be more clearly understood from the following detailed description, taken in conjunction with the accompanying drawings.

FIG. 1 is a block diagram of an example of a memory system according to some implementations.

FIG. 2 is a block diagram of an example of a storage controller according to some implementations.

FIG. 3 is a block diagram illustrating an example of a read operation performed by a first read command according to some implementations.

FIG. 4 is a block diagram illustrating an example of a read operation performed by a second read command according to some implementations.

FIG. 5 is a diagram illustrating an example of an address signal according to some implementations.

FIG. 6 is a diagram illustrating an example of a command signal transmitted when a read operation is performed by a second read command according to some implementations.

FIG. 7 is a diagram illustrating an example of a command signal transmitted when a read operation is performed by a first read command according to some implementations.

FIG. 8 is a flowchart of an example of an operating method of a memory system according to some implementations.

FIG. 9 is a flowchart illustrating an example of a process of determining a read command in an operating method of a memory system according to some implementations.

FIG. 10 is a flowchart illustrating an example of a process of determining a read command based on pre-stored read levels of a plurality of planes in an operating method of a memory system according to some implementations.

FIGS. 11 and 12 are diagrams illustrating an example of a three-dimensional vertical NAND (V-NAND) structure that may be applied to a memory device according to some implementations.

FIG. 13 is a cross-sectional view illustrating an example of a memory device having a bonding V-NAND (B-VNAND) structure, according to some implementations.

### DETAILED DESCRIPTION

Hereinafter, example implementations will be described in detail with reference to the accompanying drawings.

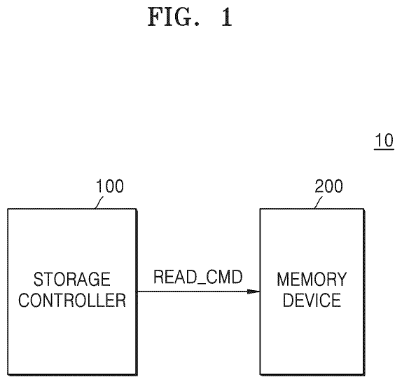

FIG. 1 is a block diagram of an example of a memory system according to some implementations. In FIG. 1, a memory system 10 may include a storage controller 100 and a memory device 200. The storage controller 100 may transmit a read command Read_CMD to the memory device 200. Hereinafter, in the present disclosure, the storage controller 100 may be understood as a hardware configuration. In addition, in the present disclosure, the memory device 200 may include a plurality of planes, and the planes of the memory device 200 may be units of storage area. In addition, in the present disclosure, read levels of a plurality of planes may refer to read voltage levels of a plurality of planes.

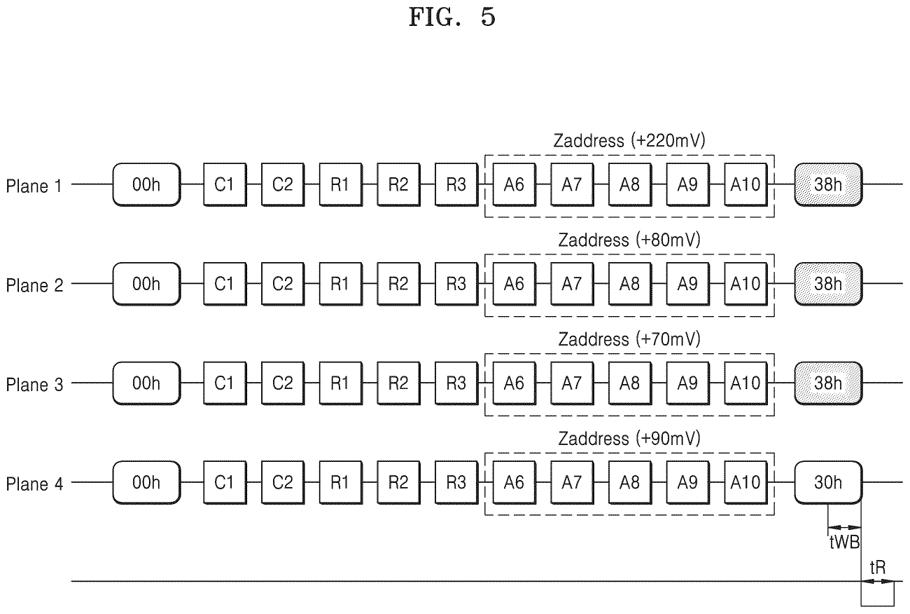

The storage controller 100 may generate a first read command signal or a second read command signal to perform a read operation on the memory device 200. The first read command signal may include an address signal set for each of the plurality of planes included in the memory device 200. For example, the plurality of planes included in the memory device 200 may each have a unique read voltage level, and the first read command signal may be configured to include an address signal corresponding to a read voltage level of each of the plurality of planes included in the memory device 200. The first read command signal is described in detail with reference to FIG. 5.

The storage controller 100 may be configured to generate a first address signal based on a read level of a first plane among the plurality of planes of the memory device 200 and generate a second address signal based on a read level of a second plane among the plurality of planes of the memory device 200. For example, the storage controller 100 may generate the first read command signal including the first address signal and the second address signal. Here, the terms “first plane” and “second plane” are simply used to distinguish the planes included in the memory device 200, and the terms “first address signal” and “second address signal” are simply used to distinguish address signals for respective planes.

The second read command signal may include an address signal applied collectively to the plurality of planes included in the memory device 200. For example, the second read command signal may be configured to include an address signal corresponding to a read level of any one plane included in the memory device 200. When a read operation is performed by the second read command signal, the planes of the memory device 200 may enter a defense protocol, and for planes on which reading has failed, a read operation may be tried again through a direct memory access (DMA) method. For example, for planes on which the read operation has failed, the memory device 200 may retry a read operation by the DMA method.

The storage controller 100 may generate the second read command signal based on a read level of a first plane among the plurality of planes of the memory device 200. For example, the storage controller 100 may generate the second read command signal based on a read voltage level of any one of the plurality of planes of the memory device 200. The first plane according to an embodiment simply refers to any one plane among the plurality of planes included in the memory device 200.

The storage controller 100 may determine either the first read command signal or the second read command signal as the read command Read_CMD and may perform a read operation on the memory device 200 based on the determined read command Read_CMD. For example, the storage controller 100 may determine either the first read command signal or the second read command signal as the read command Read_CMD and may generate the determined read command Read_CMD.

The storage controller 100 may determine either the first read command signal or the second read command signal as the read command Read_CMD, according to a preset standard. The preset standard may be a deviation in read levels of a plurality of planes. For example, the storage controller 100 may determine whether a deviation in read levels of a plurality of planes is equal to or greater than the preset standard. When it is determined that a deviation in read levels of the plurality of planes of the memory device 200 is equal to or greater than the preset standard, the storage controller 100 may determine the first read command signal as the read command Read_CMD. For example, when the deviation in the read levels of the plurality of planes is equal to or greater than the preset standard, the storage controller 100 may generate the first read command signal and may cause a read operation to be performed on each of the plurality of planes by the first read command signal. In addition, when it is determined that the deviation in the read levels of the plurality of planes does not satisfy the preset standard, the storage controller 100 may determine the second read command signal as the read command Read_CMD and may generate the second read command signal. The preset standard may be a value set at the time of manufacturing the memory device 200, but is not limited thereto.

The storage controller 100 may store a read level of each of the plurality of planes included in the memory device 200. For example, the storage controller 100 may pre-store the read level of each of the plurality of planes included in the memory device 200 and may generate the first read command signal based on the stored read level information. The first read command signal may include address signals generated based on the respective read levels of the plurality of planes included in the memory device 200.

The memory device 200 may be configured to include a plurality of planes. The plurality of planes included in the memory device 200 may have different read levels. When a read operation is performed by the first read command signal, the memory device 200 may perform a read operation based on an address signal corresponding to a read level of each of the planes. When a read operation is performed by the second read command signal, the memory device 200 may perform a read operation on all of the plurality of planes based on an address signal corresponding to a read level of any one of the plurality of planes. When a read operation is performed by the second read command signal, the memory device 200 may initiate a defense protocol for a plane. For example, when a read operation is performed on the second plane based on an address signal generated according to the read level of the first plane, a defense protocol may be initiated in the second plane. The defense protocol may be an operation for, when a read voltage indicated by an address signal and a read voltage of a read target plane of the memory device 200 do not match each other, matching the two read voltages.

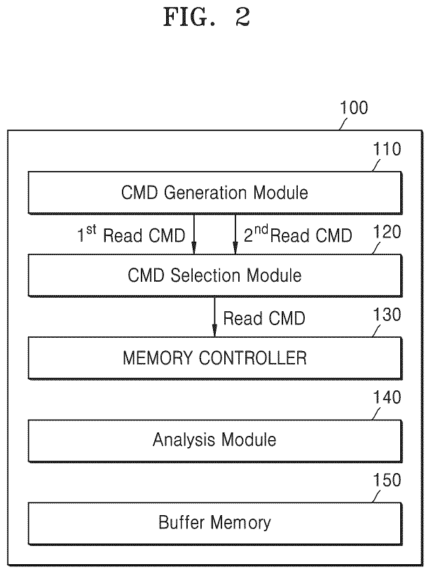

FIG. 2 is a block diagram of an example of a storage controller according to some implementations. In FIGS. 1 and 2, a storage controller 100 may include a command generation module (circuit) 110, a command selection module (circuit) 120, a memory controller 130, an analysis module (circuit) 140, or a buffer memory 150.

The command generation module 110 may generate a first read command signal 1st Read CMD including an address signal set for each of the plurality of planes of the memory device 200, or a second read command signal 2nd Read CMD including an address signal applied collectively to the plurality of planes of the memory device 200. For example, the command generation module 110 may determine the first read command signal 1st Read CMD or the second read command signal 2nd Read CMD as the read command Read_CMD, based on a preset standard, and may generate the determined signal.

When it is determined that a deviation in read levels of the plurality of planes of the memory device 200 is equal to or greater than the preset standard, the storage controller 100 may determine the first read command signal 1st Read CMD as the read command Read_CMD. For example, when the deviation in the read levels of the plurality of planes is equal to or greater than the preset standard, the storage controller 100 may generate the first read command signal 1st Read CMD and may cause a read operation to be performed on each of the plurality of planes by the first read command signal 1st Read CMD. In addition, when it is determined that the deviation in the read levels of the plurality of planes does not satisfy the preset standard, the storage controller 100 may determine the second read command signal 2nd Read CMD as the read command Read_CMD and may generate the second read command signal 2nd Read CMD.

The first read command signal 1st Read CMD may include an address signal set for each of the plurality of planes included in the memory device 200. For example, the plurality of planes included in the memory device 200 may each have a unique read voltage level, and the first read command signal 1st Read CMD may be configured to include an address signal corresponding to a read voltage level of each of the plurality of planes included in the memory device 200.

For example, the command generation module 110 may generate a first address signal based on a read level of a first plane among the plurality of planes and may generate a second address signal based on a read level of a second plane among the plurality of planes. The command generation module 110 may generate the first read command signal 1st Read CMD including the first address signal and the second address signal. Here, the terms “first plane” and “second plane” are simply used to distinguish the planes included in the memory device 200, and the terms “first address signal” and “second address signal” are simply used to distinguish address signals for respective planes.

The second read command signal 2nd Read CMD may include an address signal applied collectively to the plurality of planes included in the memory device 200. For example, the second read command signal 2nd Read CMD may be configured to include an address signal corresponding to a read level of any one plane included in the memory device 200. When a read operation is performed by the second read command signal 2nd Read CMD, the planes of the memory device 200 may enter a defense protocol, and for planes on which reading has failed, a read operation may be tried again through a DMA method. For example, for planes on which the read operation has failed, the memory device 200 may retry a read operation by the DMA method. The command selection module 120 may generate the second read command signal 2nd Read CMD based on a read level of a first plane among the plurality of planes of the memory device 200. For example, the command selection module 120 may generate the second read command signal 2nd Read CMD based on a read voltage level of any one of the plurality of planes of the memory device 200. The first plane may refer to any one plane among the plurality of planes included in the memory device 200.

The command selection module 120 may determine either the first read command signal 1st Read CMD or the second read command signal 2nd Read CMD as the read command Read_CMD. For example, the command selection module 120 may receive the first read command signal 1st Read CMD or the second read command signal 2nd Read CMD from the command generation module 110, may determine either the first read command signal 1st Read CMD or the second read command signal 2nd Read CMD as the read command Read_CMD, based on a preset standard, and may cause the command generation module 110 to generate the determined signal.

The preset standard may be a deviation in read levels of a plurality of planes. For example, the command selection module 120 may determine whether a deviation in read levels of a plurality of planes is equal to or greater than the preset standard. When it is determined that a deviation in read levels of the plurality of planes of the memory device 200 is equal to or greater than the preset standard, the command selection module 120 may determine the first read command signal 1st Read CMD as the read command Read_CMD. For example, when the deviation in the read levels of the plurality of planes is equal to or greater than the preset standard, to reduce the time required for a defense protocol of the planes when a read operation is performed by the second read command signal 2nd Read CMD, which has been generated according to one read voltage level, the command selection module 120 may cause a read operation to be performed on each of the plurality of planes by the first read command signal 1st Read CMD. The preset standard may be a value set at the time of manufacturing the memory device 200, but is not limited thereto.

The memory controller 130 may transmit the determined read command Read_CMD to the memory device 200. For example, the memory controller 130 may transmit the read command Read_CMD determined by the command selection module 120 to the memory device 200. When it is determined that the deviation in the read levels of the plurality of planes of the memory device 200 satisfies the preset standard, the command selection module 120 may determine the first read command signal 1st Read CMD as the read command Read_CMD, and the memory controller 130 may transmit the first read command signal 1st Read CMD to the memory device 200. When it is determined that the deviation in the read levels of the plurality of planes of the memory device 200 does not satisfy the preset standard, the command selection module 120 may determine the second read command signal 2nd Read CMD as the read command Read_CMD, and the memory controller 130 may transmit the second read command signal 2nd Read CMD to the memory device 200.

The analysis module 140 may determine whether a deviation in read levels of a plurality of planes is equal to or greater than a preset standard. The preset standard may be a deviation in read levels of a plurality of planes. For example, the analysis module 140 may determine whether a deviation in read levels of a plurality of planes is equal to or greater than the preset standard. The preset standard may be a value set at the time of manufacturing the memory device 200, but is not limited thereto. The analysis module 140 may transmit a result of the determination to the command selection module 120 and may cause the command selection module 120 to determine either the first read command signal 1st Read CMD or the second read command signal 2nd Read CMD as the read command Read_CMD.

The buffer memory 150 may store a read level of each of the plurality of planes included in the memory device 200. For example, the buffer memory 150 may pre-store the read level of each of the plurality of planes included in the memory device 200, and the command generation module 110 may generate the first read command signal 1st Read CMD based on the stored read level information. The first read command signal 1st Read CMD may include address signals generated based on the respective read levels of the plurality of planes included in the memory device 200.

The storage controller 100 may set the read command Read_CMD differently according to the read levels of the plurality of planes included in the memory device 200, thereby reducing the time and power required for the defense protocol. For example, when it is determined that the read levels of the plurality of planes included in the memory device 200 are equal to or greater than the preset standard, the storage controller 100 may set an address signal for each of the planes and perform a read operation thereon, based on the first read command signal 1st Read CMD, thereby preventing the defense protocol from being initiated in the memory device 200.

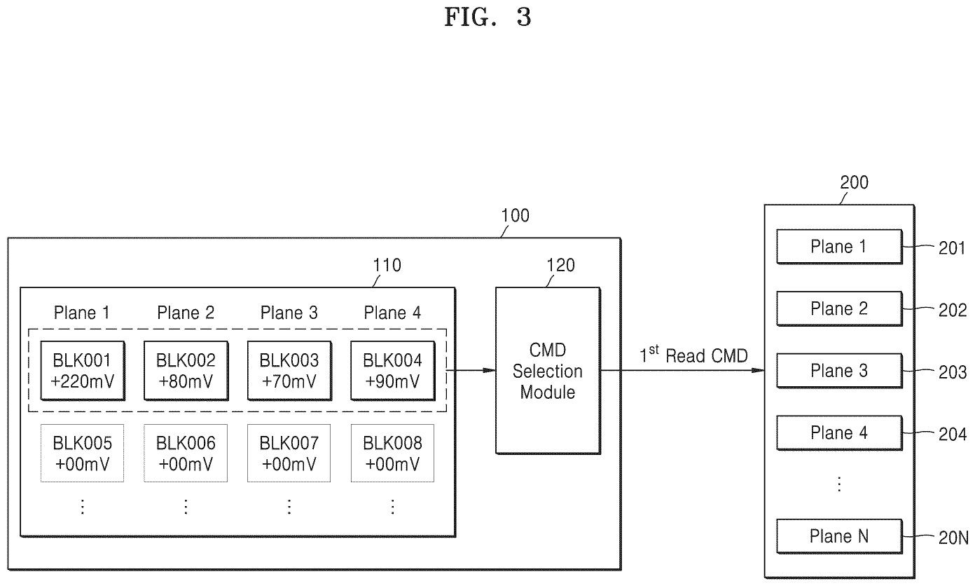

FIG. 3 is a block diagram illustrating an example of a read operation performed by a first read command according to some implementations. In FIGS. 2 and 3, the storage controller 100 may include the command generation module 110 or the command selection module 120, and the memory device 200 may include a plurality of planes, namely, first to nth planes 201, 202, 203, 204, . . . , and 20N.

The command generation module 110 may set different address signal levels according to read levels of the first to nth planes 201, 202, 203, 204, . . . , and 20N.

For example, when a read level of the first plane 201 (hereinafter, also referred to as a “first plane Plane 1”) is 220 mV, a read level of the second plane 202 (hereinafter, also referred to as a “second plane Plane 2”) is 80 mV, a read level of the third plane 203 (hereinafter, also referred to as a “third plane Plane 3”) is 70 mV, and a read level of the fourth plane 204 (hereinafter, also referred to as a “fourth plane Plane 4”) is 90 mV, the command generation module 110 may set an address signal level for the first plane 201 to 220 mV, may set an address signal level for the second plane 202 to 80 mV, may set an address signal level for the third plane 203 to 70 mV, and may set an address signal level for the fourth plane 204 to 90 mV, thereby generating the first read command signal 1st Read CMD. Although FIG. 3 illustrates only a case in which different address signal levels are set for the first plane 201, the second plane 202, the third plane 203, and the fourth plane 204, the number of planes is not limited thereto, and the storage controller 100 may generate the first read command signal 1st Read CMD with different address levels set for a plurality of planes.

The command generation module 110 may set different address levels for a plurality of memory blocks BLK001, BLK002, BLK003, BLK004, BLK005, BLK006, BLK007, and BLK008 present in respective planes. However, the number of memory blocks BLK001, BLK002, BLK003, BLK004, BLK005, BLK006, BLK007, and BLK008 is not limited to the implementations of FIG. 3.

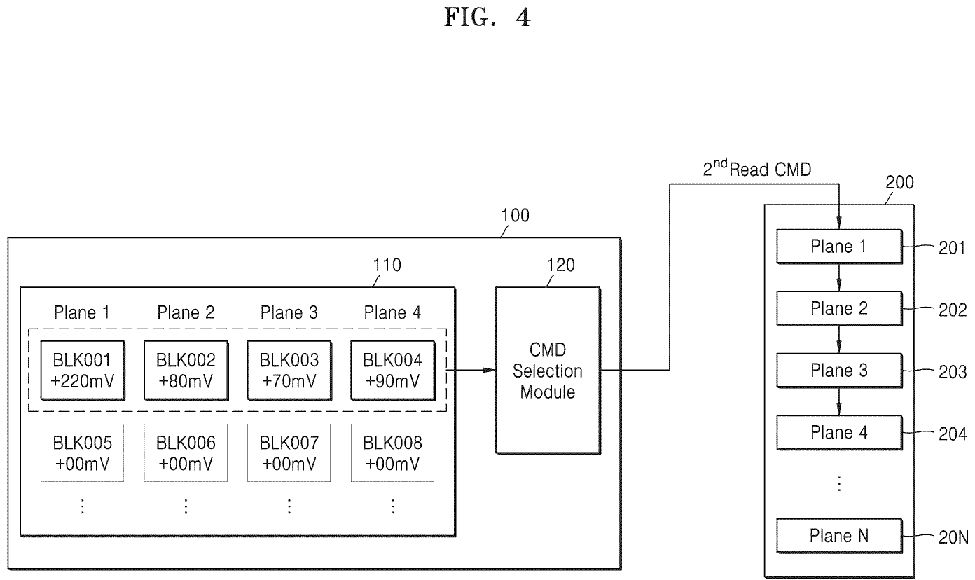

FIG. 4 is a block diagram illustrating an example of a read operation performed by a second read command according to some implementations. In FIGS. 2 and 4, the storage controller 100 may include the command generation module 110 or the command selection module 120, and the memory device 200 may include a plurality of planes, namely, first to nth planes 201, 202, 203, 204, . . . , and 20N.

When a read operation is performed by the second read command signal 2nd Read CMD, the command generation module 110 may set different address signal levels according to read levels of the first to nth planes 201, 202, 203, 204, . . . , and 20N.

For example, when a read level of the first plane 201 (hereinafter, also referred to as a “first plane Plane 1”) is 220 mV, a read level of the second plane 202 (hereinafter, also referred to as a “second plane Plane 2”) is 80 mV, a read level of the third plane 203 (hereinafter, also referred to as a “third plane Plane 3”) is 70 mV, and a read level of the fourth plane 204 (hereinafter, also referred to as a “fourth plane Plane 4”) is 90 mV, the command generation module 110 may generate the second read command signal 2nd Read CMD based on an address signal level for the first plane 201. For example, the second read command signal 2nd Read CMD may be configured to have an address signal level of 220 mV. When a read operation is performed by the second read command signal 2nd Read CMD, the memory device 200 may initiate a defense protocol when performing a read operation on planes other than the first plane 201. For example, when a read operation is performed by the second read command signal 2nd Read CMD, the memory device 200 may perform a defense protocol on the second plane 202, the third plane 203, and the fourth plane 204 and may adjust address signal levels for the second plane 202, the third plane 203, and the fourth plane 204.

Although FIG. 4 illustrates only a case in which the same address signal level is set for the first plane 201, the second plane 202, the third plane 203, and the fourth plane 204, the number of planes is not limited thereto, and the storage controller 100 may generate the first read command signal 1st Read CMD with the same address level set for a plurality of planes.

The command generation module 110 may set different address levels for a plurality of memory blocks BLK001, BLK002, BLK003, BLK004, BLK005, BLK006, BLK007, and BLK008 present in respective planes. However, the number of memory blocks BLK001, BLK002, BLK003, BLK004, BLK005, BLK006, BLK007, and BLK008 is not limited to the implementation of FIG. 4.

FIG. 5 is a diagram illustrating an example of an address signal according to some implementations. In FIGS. 2 and 5, the storage controller 100 may generate an address signal by using a 00h-30h command and a 00h-38h command. Each of the 00h-30h command and the 00h-38h command may be based on the size of a data stream constituting the command, and the 00h-30h command may include less data than the 00h-38h command. Each of the 00h-30h command and the 00h-38h command may simply be a unit of the size of a data stream constituting the command.

For example, when an address signal level Zaddress of the first plane Plane 1 is 220 mV, the storage controller 100 may generate a first address signal to include information on the address signal level Zaddress of the first plane Plane 1 in columns A6 to A10 while configuring a command having a size of 00h-38h. As another example, when an address signal level Zaddress of the second plane Plane 2 is 80 mV, the storage controller 100 may generate a second address signal to include information on the address signal level Zaddress of the second plane Plane 2 in columns A6 to A10 while configuring a command having a size of 00h-38h. As another example, when an address signal level Zaddress of the third plane Plane 3 is 70 mV, the storage controller 100 may generate a third address signal to include information on the address signal level Zaddress of the third plane Plane 3 in columns A6 to A10 while configuring a command having a size of 00h-38h.

As another example, when an address signal level Zaddress of the fourth plane Plane 4 is 90 mV, the storage controller 100 may generate a fourth address signal to include information on the address signal level Zaddress of the fourth plane Plane 4 in columns A6 to A10 while configuring a command having a size of 00h-30h. When the fourth address signal is included in a command signal having a size of 00h-30h, the size of the command signal including the fourth address signal may be configured to be smaller by tWB+tR compared to a command signal including the first address signal, the second address signal, or the third address signal.

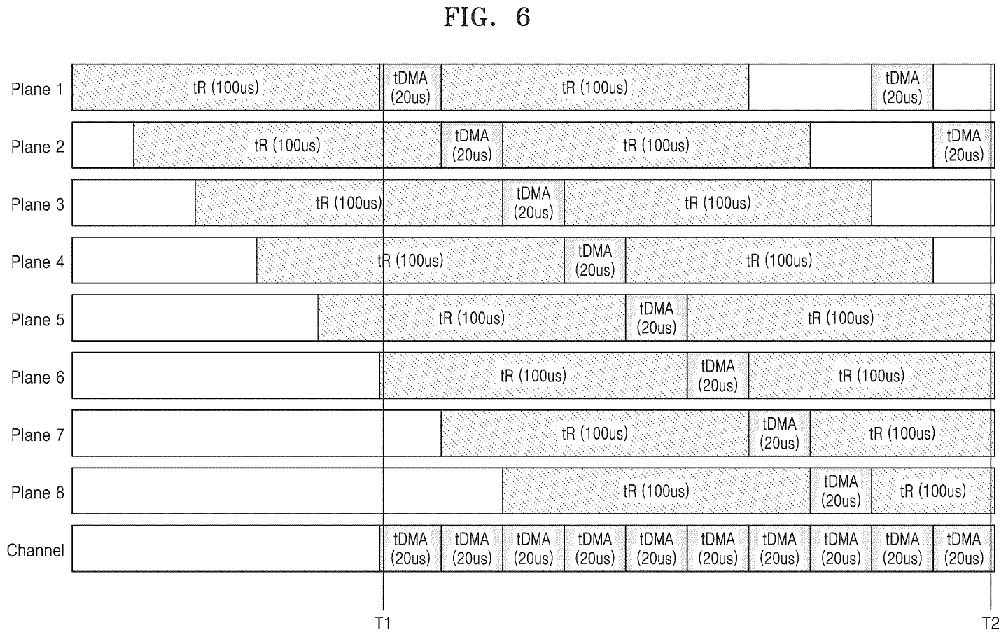

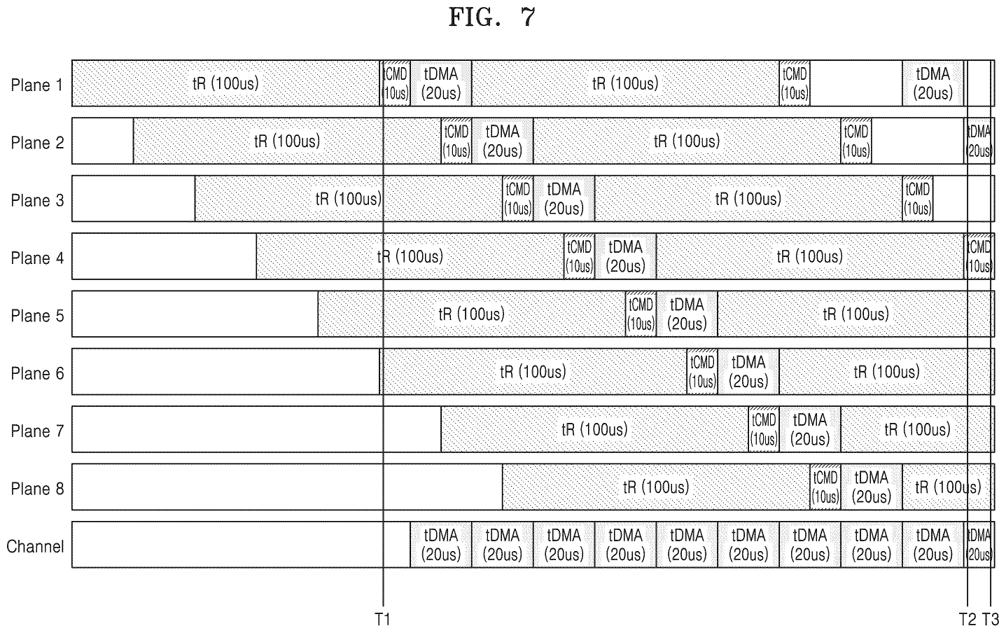

FIG. 6 is a diagram illustrating an example of a command signal transmitted when a read operation is performed by a second read command according to some implementations, and FIG. 7 is a diagram illustrating an example of a command signal transmitted when a read operation is performed by a first read command according to some implementations.

In FIG. 6, when a read operation is performed by the second read command signal 2nd Read CMD, a read operation tR may be performed by a command signal having one address signal level, and a defense protocol tDMA based on a direct memory access (DMA) method may be performed after each read operation tR. For example, when a read operation is performed on first to eighth planes Plane 1, Plane 2, Plane 3, Plane 4, Plane 5, Plane 6, Plane 7, and Plane 8, a total of 10 defense protocols tDMA may be performed from a first time point T1 to a second time point T2. According to some implementations, the first time point T1 may be a read command start time point for the first plane Plane 1, and the second time point T2 may be a read command end time point for the eighth plane Plane 8.

In FIG. 7, in comparison with FIG. 6, when a read operation is performed by the first read command signal 1st Read CMD, the read operation tR may be performed by a command signal having an address signal level for each plane, and a command signal setting tCMD may be further performed after each read operation tR. For example, when a read operation is performed on the first to eighth planes Plane 1, Plane 2, Plane 3, Plane 4, Plane 5, Plane 6, Plane 7, and Plane 8, a total of 10 defense protocols tDMA and a total of 8 command signal settings tCMD may be performed from the first time point T1 to a third time point T3. According to some implementations, the first time point T1 may be a read command start time point for the first plane Plane 1, and the second time point T2 may be a read command end time point for the eighth plane Plane 8 when a read operation is performed by the second read command signal 2nd Read CMD. In addition, the third time point T3 may be a read command end time point for the eighth plane Plane 8 when a read operation is performed by the second read command signal 2nd Read CMD.

In FIG. 7, in comparison with FIG. 6, when a read operation is performed by the first read command signal 1st Read CMD, the time required for a read command may increase by the command signal setting tCMD, compared to when a read operation is performed by the second read command signal 2nd Read CMD. However, the time required for the command signal setting tCMD may be only 10 us at most. For example, an interval between the second time point T2 and the third time point T3 may be only 10 us at most, and in a sequential read mode, there may be an effect such that the time required for the command signal setting tCMD is overshadowed by the time required for the defense protocol tDMA. Thus, when a read operation is performed by the first read command signal 1st Read CMD, the storage controller 100 may perform a read operation for substantially the same time as when a read operation is performed by the second read command signal 2nd Read CMD. The memory system 10 of FIG. 1 may perform a command signal setting tCMD operation and a read operation and thus may have increased read performance in substantially the same time as in the implementation of FIG. 6.

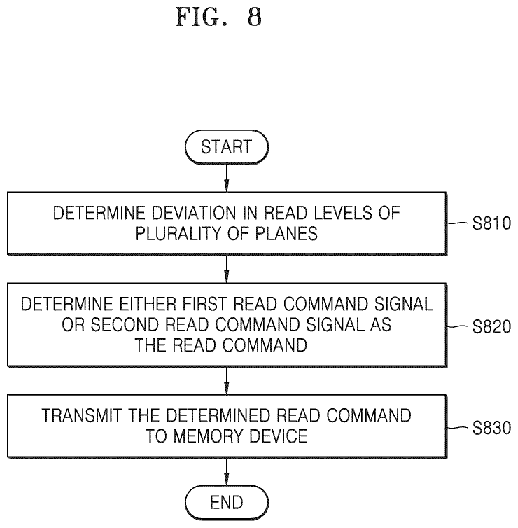

FIG. 8 is a flowchart of an example of an operating method of a memory system according to some implementations. In FIGS. 1 and 8, the memory system 10 may determine a deviation in read levels of a plurality of planes (S810). For example, the storage controller 100 may determine whether a deviation in read levels of a plurality of planes is equal to or greater than a preset standard.

When the first read command signal 1st Read CMD or the second read command signal 2nd Read CMD is generated, the memory system 10 may determine either the first read command signal 1st Read CMD or the second read command signal 2nd Read CMD as the read command Read_CMD (S820).

The first read command signal 1st Read CMD may include an address signal set for each of the plurality of planes included in the memory device 200. For example, the plurality of planes included in the memory device 200 may each have a unique read voltage level, and the first read command signal 1st Read CMD may be configured to include an address signal corresponding to a read voltage level of each of the plurality of planes included in the memory device 200. The storage controller 100 may be configured to generate a first address signal based on a read level of a first plane among the plurality of planes of the memory device 200 and generate a second address signal based on a read level of a second plane among the plurality of planes of the memory device 200. For example, the storage controller 100 may generate the first read command signal 1st Read CMD including the first address signal and the second address signal. Here, the terms “first plane” and “second plane” are simply used to distinguish the planes included in the memory device 200, and the terms “first address signal” and “second address signal” are simply used to distinguish address signals for respective planes.

The second read command signal 2nd Read CMD may include an address signal applied collectively to the plurality of planes included in the memory device 200. For example, the second read command signal 2nd Read CMD may be configured to include an address signal corresponding to a read level of any one plane included in the memory device 200. When a read operation is performed by the second read command signal 2nd Read CMD, the planes of the memory device 200 may enter a defense protocol, and for planes on which reading has failed, a read operation may be tried again through a DMA method. For example, for planes on which the read operation has failed, the memory device 200 may retry a read operation by the DMA method. The storage controller 100 may generate the second read command signal 2nd Read CMD based on a read level of a first plane among the plurality of planes of the memory device 200. For example, the storage controller 100 may generate the second read command signal 2nd Read CMD based on a read voltage level of any one of the plurality of planes of the memory device 200. The first plane may refer to any one plane among the plurality of planes included in the memory device 200.

The storage controller 100 may determine either the first read command signal 1st Read CMD or the second read command signal 2nd Read CMD as the read command Read_CMD, according to a preset standard. The preset standard may be a deviation in read levels of a plurality of planes. The preset standard may be a value set at the time of manufacturing the memory device 200, but is not limited thereto.

When the read command Read_CMD is determined, the determined read command Read_CMD may be transmitted to the memory device 200 (S830). The storage controller 100 may determine either the first read command signal 1st Read CMD or the second read command signal 2nd Read CMD as the read command Read_CMD and may perform a read operation on the memory device 200 based on the determined read command Read_CMD.

When a read operation is performed by the first read command signal 1st Read CMD, the memory device 200 may perform a read operation based on an address signal corresponding to a read level of each of the planes. When a read operation is performed by the second read command signal 2nd Read CMD, the memory device 200 may perform a read operation on all of the plurality of planes, based on an address signal corresponding to a read level of any one of the plurality of planes. When a read operation is performed by the second read command signal 2nd Read CMD, the memory device 200 may initiate a defense protocol for a plane. For example, when a read operation is performed on the second plane based on an address signal generated according to the read level of the first plane, a defense protocol may be initiated in the second plane. The defense protocol may be an operation for, when a read voltage indicated by an address signal and a read voltage of a read target plane of the memory device 200 do not match each other, matching the two read voltages.

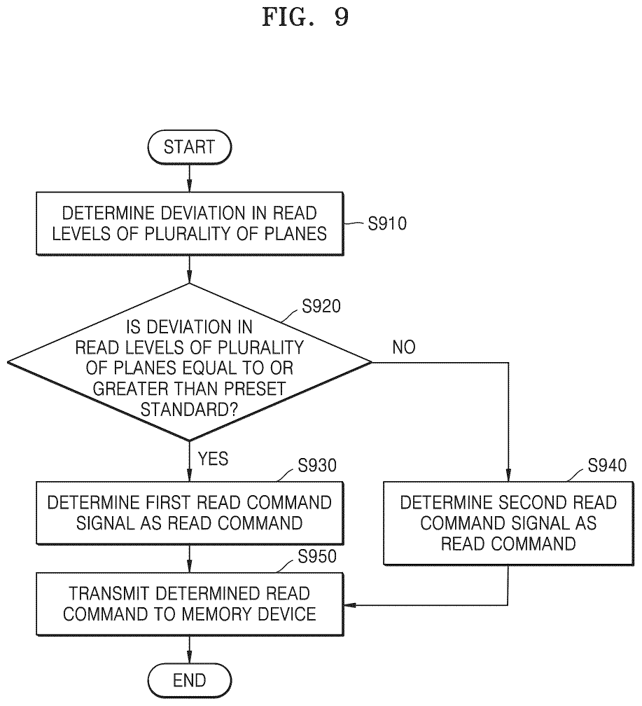

FIG. 9 is a flowchart illustrating an example of a process of determining a read command in an operating method of a memory system according to some implementations. In FIGS. 1, 2, and 9, the memory system 10 may determine a deviation in read levels of a plurality of planes (S910). For example, the storage controller 100 may determine whether a deviation in read levels of a plurality of planes is equal to or greater than a preset standard.

The memory system 10 may determine whether the deviation in the read levels of the plurality of planes is equal to or greater than a preset standard (S920). For example, the memory system 10 may determine either the first read command signal 1st Read CMD or the second read command signal 2nd Read CMD as the read command Read_CMD, based on the preset standard. The preset standard may be a deviation in read levels of a plurality of planes. For example, the memory system 10 may determine whether the deviation in the read levels of the plurality of planes is equal to or greater than the preset standard.

The first read command signal 1st Read CMD may include an address signal set for each of the plurality of planes included in the memory device 200. For example, the plurality of planes included in the memory device 200 may each have a unique read voltage level, and the first read command signal 1st Read CMD may be configured to include an address signal corresponding to a read voltage level of each of the plurality of planes included in the memory device 200.

The memory system 10 may generate the second read command signal 2nd Read CMD including an address signal applied collectively to the plurality of planes.

The second read command signal 2nd Read CMD may include an address signal applied collectively to the plurality of planes included in the memory device 200. For example, the second read command signal 2nd Read CMD may be configured to include an address signal corresponding to a read level of any one plane included in the memory device 200.

When it is determined that the deviation in the read levels of the plurality of planes is equal to or greater than the preset standard, the memory system 10 may determine the first read command signal 1st Read CMD as the read command Read_CMD (S930).

When it is determined that the deviation in the read levels of the plurality of planes of the memory device 200 is equal to or greater than the preset standard, the memory system 10 may determine the first read command signal 1st Read CMD as the read command Read_CMD. For example, when the deviation in the read levels of the plurality of planes is equal to or greater than the preset standard, to reduce the time required for a defense protocol of the planes when a read operation is performed by the second read command signal 2nd Read CMD, which has been generated according to one read voltage level, the memory system 10 may cause a read operation to be performed on each of the plurality of planes by the first read command signal 1st Read CMD. The preset standard may be a value set at the time of manufacturing the memory device 200, but is not limited thereto.

However, when it is determined that the deviation in the read levels of the plurality of planes is not equal to or greater than the preset standard, the memory system 10 may determine the second read command signal 2nd Read CMD as the read command Read_CMD (S940).

The second read command signal 2nd Read CMD may include an address signal applied collectively to the plurality of planes included in the memory device 200. For example, the second read command signal 2nd Read CMD may be configured to include an address signal corresponding to a read level of any one plane included in the memory device 200. When a read operation is performed by the second read command signal 2nd Read CMD, the planes of the memory device 200 may enter a defense protocol, and for planes on which reading has failed, a read operation may be tried again through a DMA method. For example, for planes on which the read operation has failed, the memory device 200 may retry a read operation by the DMA method. The command selection module 120 according to an embodiment may generate the second read command signal 2nd Read CMD based on a read level of a first plane among the plurality of planes of the memory device 200. For example, the command selection module 120 may generate the second read command signal 2nd Read CMD based on a read voltage level of any one of the plurality of planes of the memory device 200. The first plane may refer to any one plane among the plurality of planes included in the memory device 200.

When the read command Read_CMD is determined, the memory system 10 may transmit the determined read command Read_CMD to the memory device 200 (S950).

The memory system 10 may transmit the determined read command Read_CMD to the memory device 200. When it is determined that the deviation in the read levels of the plurality of planes of the memory device 200 satisfies the preset standard, the memory system 10 may determine the first read command signal 1st Read CMD as the read command Read_CMD and may transmit the first read command signal 1st Read CMD to the memory device 200. When it is determined that the deviation in the read levels of the plurality of planes of the memory device 200 does not satisfy the preset standard, the memory system 10 may determine the second read command signal 2nd Read CMD as the read command Read_CMD and may transmit the second read command signal 2nd Read CMD to the memory device 200.

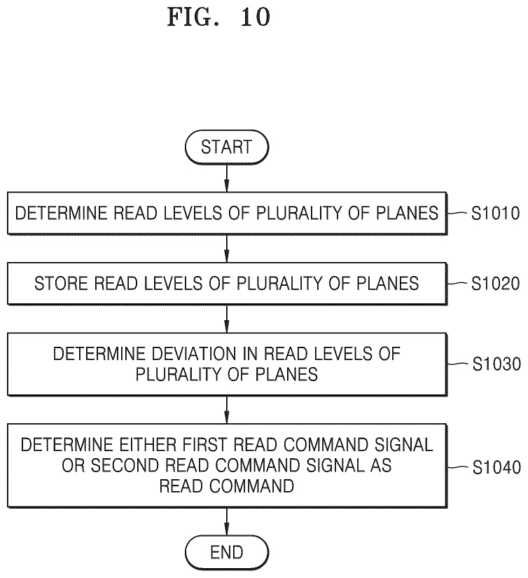

FIG. 10 is a flowchart illustrating an example of a process of determining a read command based on pre-stored read levels of a plurality of planes in an operating method of a memory system according to some implementations. In FIGS. 1, 2, and 10, the memory system 10 may determine read levels of a plurality of planes (S1010).

The memory system 10 may determine whether a deviation in the read levels of the plurality of planes is equal to or greater than a preset standard. The preset standard may be a deviation in read levels of a plurality of planes. For example, the memory system 10 may determine whether the deviation in the read levels of the plurality of planes is equal to or greater than the preset standard. The preset standard may be a value set at the time of manufacturing the memory device 200, but is not limited thereto. The memory system 10 may transmit a result of the determination to the command selection module 120 and may cause the command selection module 120 to determine either the first read command signal 1st Read CMD or the second read command signal 2nd Read CMD as the read command Read_CMD.

When the read levels of the plurality of planes are determined, the memory system 10 may store the read levels of the plurality of planes (S1020).

The memory system 10 may store a read level of each of the plurality of planes included in the memory device 200. For example, the memory system 10 may pre-store the read level of each of the plurality of planes included in the memory device 200 and may generate the first read command signal 1st Read CMD based on the stored read level information. The first read command signal 1st Read CMD may include address signals generated based on the respective read levels of the plurality of planes included in the memory device 200.

The memory system 10 may determine a deviation in the read levels of the plurality of planes (S1030). For example, the storage controller 100 may determine whether the deviation in the read levels of the plurality of planes is equal to or greater than the preset standard. When the first read command signal 1st Read CMD or the second read command signal 2nd Read CMD is generated, the memory system 10 may determine either the first read command signal 1st Read CMD or the second read command signal 2nd Read CMD as the read command Read_CMD (S1040).

The first read command signal 1st Read CMD may include an address signal set for each of the plurality of planes included in the memory device 200. For example, the plurality of planes included in the memory device 200 may each have a unique read voltage level, and the first read command signal 1st Read CMD may be configured to include an address signal corresponding to a read voltage level of each of the plurality of planes included in the memory device 200.

The second read command signal 2nd Read CMD may include an address signal applied collectively to the plurality of planes included in the memory device 200. For example, the second read command signal 2nd Read CMD may be configured to include an address signal corresponding to a read level of any one plane included in the memory device 200. When a read operation is performed by the second read command signal 2nd Read CMD, the planes of the memory device 200 may enter a defense protocol, and for planes on which reading has failed, a read operation may be tried again through a DMA method. For example, for planes on which the read operation has failed, the memory device 200 may retry the read operation by the DMA method. The storage controller 100 may generate the second read command signal 2nd Read CMD based on a read level of a first plane among the plurality of planes of the memory device 200. The first plane may refer to any one plane among the plurality of planes included in the memory device 200.

The storage controller 100 may determine either the first read command signal 1st Read CMD or the second read command signal 2nd Read CMD as the read command Read_CMD, according to a preset standard. The preset standard may be a deviation in read levels of a plurality of planes. The preset standard may be a value set at the time of manufacturing the memory device 200, but is not limited thereto.

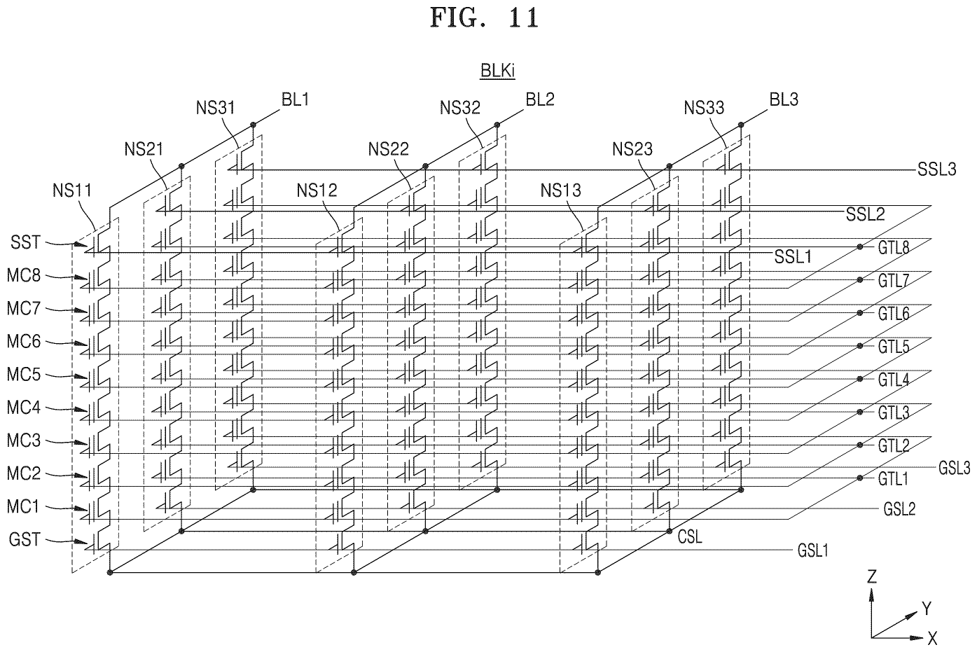

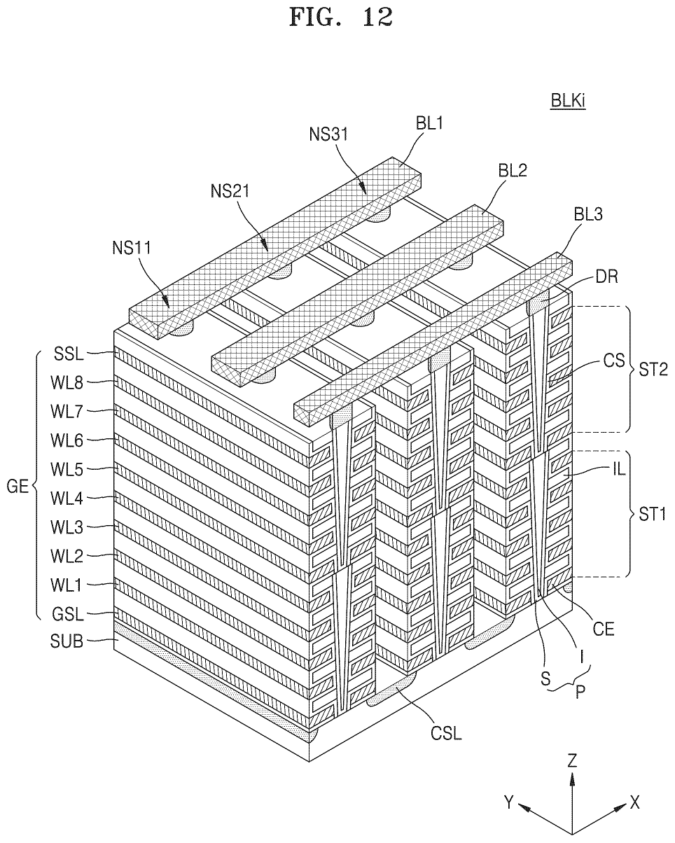

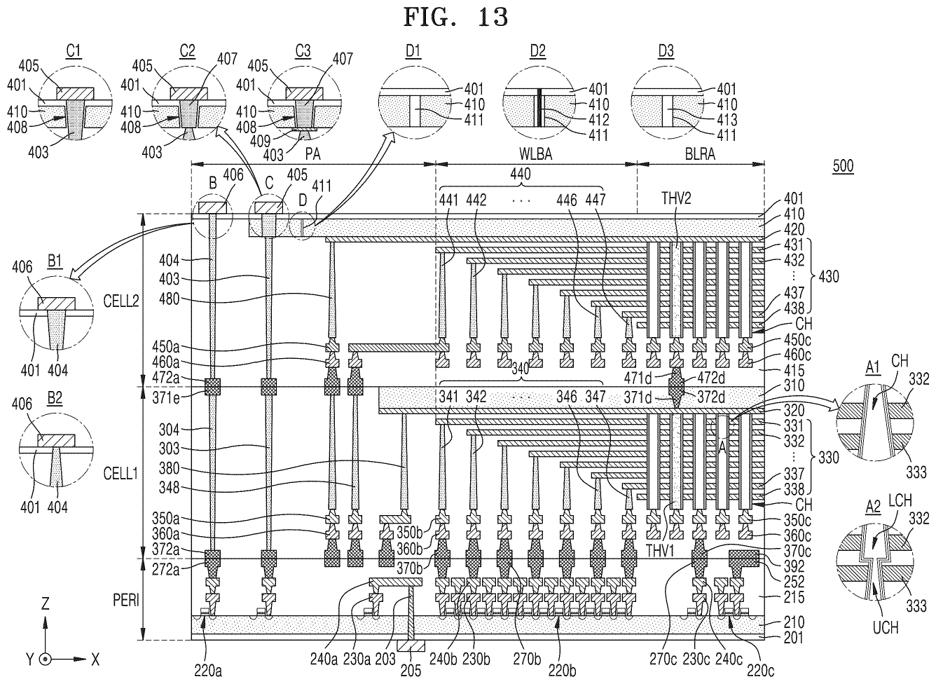

FIGS. 11 and 12 are diagrams illustrating an example of a three-dimensional vertical NAND (V-NAND) structure that may be applied to a memory device according to some implementations, and FIG. 13 is a cross-sectional view illustrating an example of a memory device having a bonding V-NAND (B-VNAND) structure according to some implementations.

A non-volatile memory applicable to the memory device 200 (see FIG. 1) may include a plurality of memory blocks. FIGS. 11 and 12 illustrate the structure of a memory block BLKi, which is any one of the plurality of memory blocks, and FIG. 13 illustrates an implementation of a memory device 500 including the non-volatile memory.

In FIG. 11, the memory block BLKi may include a plurality of memory NAND strings NS11 to NS33 connected between bit lines BL1, BL2, and BL3 and a common source line CSL. Each of the plurality of memory NAND strings NS11 to NS33 may include a string select transistor SST, a plurality of memory cells MC1 to MC8, and a ground select transistor GST. For simplicity of the drawing, FIG. 11 illustrates that each of the plurality of memory NAND strings NS11 to NS33 includes eight memory cells MC1 to MC8, but the present disclosure is not limited thereto.

The string select transistor SST may be connected to a corresponding string select line among string select lines SSL1, SSL2, and SSL3. The plurality of memory cells MC1 to MC8 may be respectively connected to corresponding gate lines among gate lines GTL1 to GTL8. The gate lines GTL1 to GTL8 may correspond to word lines, and some of the gate lines GTL1 to GTL8 may correspond to dummy word lines. The ground select transistor GST may be connected to a corresponding ground select line among ground select lines GSL1, GSL2, and GSL3. The string select transistor SST may be connected to a corresponding bit line among the bit lines BL1, BL2, and BL3, and the ground select transistor GST may be connected to the common source line CSL.

Gate lines (e.g., GTL1) at the same height may be connected in common, and the ground select lines GSL1, GSL2, and GSL3 and the string select lines SSL1, SSL2, and SSL3 may be separated from each other. FIG. 11 illustrates that the memory block BLKi is connected to eight gate lines GTL1 to GTL8 and three bit lines BL1, BL2, and BL3, but the present disclosure is not limited thereto.

In FIG. 12, the memory block BLKi may be formed in a direction vertical to a substrate SUB. Memory cells constituting the memory NAND strings NS11 to NS33 may be formed by being stacked on a plurality of semiconductor layers.

The common source line CSL extending in a first direction (a Y direction) may be provided on the substrate SUB. A plurality of insulating layers IL extending in the first direction (the Y direction) may be sequentially provided in a third direction (a Z direction) on a region of the substrate SUB between two adjacent common source lines CSL, and the plurality of insulating layers IL may be separated from each other by a certain distance in the third direction (the Z direction). A plurality of pillars P, which are sequentially arranged in the first direction (the Y direction) and pass through the plurality of insulating layers IL in the third direction (the Z direction), may be provided on a region of the substrate SUB between two adjacent common source lines CSL. The plurality of pillars P may pass through the plurality of insulating layers IL and may be in contact with the substrate SUB. A surface layer S of each of the pillars P may include a silicon material doped with an impurity of a first conductivity type and may function as a channel region.

An inner layer I of each of the pillars P may include an insulating material, such as silicon oxide, or an air gap. A charge storage layer CS may be provided along the insulating layers IL, the pillars P, and an exposed surface of the substrate SUB, in a region between two adjacent common source lines CSL. The charge storage layer CS may include a gate insulating layer (also referred to as a “tunneling insulating layer”), a charge trap layer, and a blocking insulating layer. In addition, a gate electrode GE including select lines GSL and SSL and word lines WL1 to WL8 may be provided on an exposed surface of the charge storage layer CS, in a region between two adjacent common source lines CSL. Drains or drain contacts DR may be respectively provided on the plurality of pillars P. The bit lines BL1 to BL3, which extend in a second direction (an X direction) and are separated from each other by a certain distance in the first direction (the Y direction), may be provided on the drain contacts DR.

In FIG. 12, each of the memory NAND strings NS11 to NS33 may be implemented in a structure in which a first memory stack ST1 and a second memory stack ST2 are stacked. The first memory stack ST1 may be connected to the common source line CSL, the second memory stack ST2 may be connected to the bit lines BL1 to BL3, and the first memory stack ST1 and the second memory stack ST2 may be stacked to share a channel hole with each other.

In FIG. 13, the memory device 500 may have a chip-to-chip (C2C) structure. Here, the C2C structure may refer to a structure provided by individually manufacturing at least one upper chip including a cell region CELL and a lower chip including a peripheral circuit region PERI, and then connecting the at least one upper chip and the lower chip to each other by a bonding method. For example, the bonding method may refer to a method of electrically or physically connecting a bonding metal pattern formed on the uppermost metal layer of an upper chip and a bonding metal pattern formed on the uppermost metal layer of a lower chip to each other. For example, when the bonding metal patterns include copper (Cu), the bonding method may be a Cu—Cu bonding method. As another example, the bonding metal patterns may include aluminum (Al) or tungsten (W).

The memory device 500 may include at least one upper chip including a cell region. For example, as shown in FIG. 13, the memory device 500 may be implemented to include two upper chips. However, the number of upper chips is not limited thereto. When the memory device 500 is implemented to include two upper chips, the memory device 500 may be manufactured by manufacturing a first upper chip including a first cell region CELL1, a second upper chip including a second cell region CELL2, and a lower chip including the peripheral circuit region PERI, and then, connecting the first upper chip, the second upper chip, and the lower chip to each other by a bonding method. The first upper chip may be inverted and connected to the lower chip by a bonding method, and the second upper chip may also be inverted and connected to the first upper chip by a bonding method. In the following description, upper and lower portions of the first and second upper chips are defined based on before the first upper chip and the second upper chip are inverted. That is, in FIG. 13, an upper portion of the lower chip refers to an upper portion defined based on a +Z-axis direction, and an upper portion of each of the first and second upper chips refers to an upper portion defined based on a −Z-axis direction. However, this is an example, and only one of the first upper chip and the second upper chip may be inverted and connected by a bonding method.

Each of the peripheral circuit region PERI and the first and second cell regions CELL1 and CELL2 of the memory device 500 may include an external pad bonding region PA, a word line bonding region WLBA, and a bit line bonding region BLBA.

The peripheral circuit region PERI may include a first substrate 210 and a plurality of circuit elements 220a, 220b, and 220c formed on the first substrate 210. An interlayer insulating layer 215 including at least one insulating layer may be provided on the plurality of circuit elements 220a, 220b, and 220c, and a plurality of metal wirings connecting the plurality of circuit elements 220a, 220b, and 220c to each other may be provided in the interlayer insulating layer 215. For example, the plurality of metal wirings may include first metal wirings 230a, 230b, and 230c respectively connected to the plurality of circuit elements 220a, 220b, and 220c, and second metal wirings 240a, 240b, and 240c respectively formed on the first metal wirings 230a, 230b, and 230c. The plurality of metal wirings may include at least one of various conductive materials. For example, the first metal wirings 230a, 230b, and 230c may include tungsten having a relatively high electrical resistivity and the second metal wirings 240a, 240b, and 240c may include copper having a relatively low electrical resistivity.

In the present disclosure, only the first metal wirings 230a, 230b, and 230c and the second metal wirings 240a, 240b, and 240c are shown and described, but the present disclosure is not limited thereto, and at least one additional metal wiring may be further formed on the second metal wirings 240a, 240b, and 240c. In this case, the second metal wirings 240a, 240b, and 240c may include aluminum. In addition, at least some of the additional metal wirings formed on the second metal wirings 240a, 240b, and 240c may include copper having a lower electrical resistivity than aluminum included in the second metal wirings 240a, 240b, and 240c.

The interlayer insulating layer 215 may be arranged on the first substrate 210 and may include an insulating material, such as silicon oxide or silicon nitride.

Each of the first and second cell regions CELL1 and CELL2 may include at least one memory block. The first cell region CELL1 may include a second substrate 310 and a common source line 320. A plurality of word lines 331 to 338 (330) may be stacked on the second substrate 310 in a direction (a Z-axis direction) perpendicular to an upper surface of the second substrate 310. String select lines and a ground select line may be arranged above and below the plurality of word lines 330, and the plurality of word lines 330 may be arranged between the string select lines and the ground select line. Likewise, the second cell region CELL2 may include a third substrate 410 and a common source line 420, and a plurality of word lines 431 to 438 (430) may be stacked in a direction (the Z-axis direction) perpendicular to an upper surface of the third substrate 410. The second substrate 310 and the third substrate 410 may include various materials and may each be, for example, a silicon substrate, a silicon-germanium substrate, a germanium substrate, or a substrate having a monocrystalline epitaxial layer grown on a monocrystalline silicon substrate. A plurality of channel structures CH may be formed in each of the first and second cell regions CELL1 and CELL2.

In some implementations, such as that shown in A1, the channel structure CH may be provided in the bit line bonding region BLBA, may extend in a direction perpendicular to the upper surface of the second substrate 310, and may pass through the word lines 330, the string select lines, and the ground select line. The channel structure CH may include a data storage layer, a channel layer, and a buried insulating layer. The channel layer may be electrically connected to a first metal wiring 350c and a second metal wiring 360c in the bit line bonding region BLBA. For example, the second metal wiring 360c may be a bit line and may be connected to the channel structure CH through the first metal wiring 350c. The second metal wiring 360c (hereinafter, also referred to as a “bit line 360c”) may extend in a first direction (a Y-axis direction) parallel to the upper surface of the second substrate 310.

In some implementations, such as that shown in A2, the channel structure CH may include a lower channel LCH and an upper channel UCH connected to each other. For example, the channel structure CH may be formed through a process of forming the lower channel LCH and a process of forming the upper channel UCH. The lower channel LCH may extend in a direction perpendicular to the upper surface of the second substrate 310 and may pass through the common source line 320 and lower word lines 331 and 332. The lower channel LCH may include a data storage layer, a channel layer, and a buried insulating layer and may be connected to the upper channel UCH. The upper channel UCH may pass through upper word lines 333 to 338. The upper channel UCH may include a data storage layer, a channel layer, and a buried insulating layer, and the channel layer of the upper channel UCH may be electrically connected to the first metal wiring 350c and the second metal wiring 360c. As the length of a channel increases, it may be difficult to form a channel having a constant width due to process reasons. The memory device 500 according to some implementations may include a channel having improved width uniformity due to the lower channel LCH and the upper channel UCH, which are formed through sequential processes.

As shown in A2, when the channel structure CH is formed to include the lower channel LCH and the upper channel UCH, a word line positioned near a boundary between the lower channel LCH and the upper channel UCH may be a dummy word line. For example, the word line 332 and the word line 333 forming the boundary between the lower channel LCH and the upper channel UCH may each be a dummy word line. In this case, data may not be stored in memory cells connected to the dummy word line. In some implementations, the number of pages corresponding to memory cells connected to the dummy word line may be less than the number of pages corresponding to memory cells connected to a general word line. A voltage level applied to the dummy word line may be different from a voltage level applied to the general word line, and thus, the effect of a non-uniform channel width between the lower channel LCH and the upper channel UCH on the operation of the memory device 500 may be reduced.

In A2, the number of lower word lines 331 and 332 through which the lower channel LCH passes is less than the number of upper word lines 333 to 338 through which the upper channel UCH passes. However, this is an example, and the present disclosure is not limited thereto. As another example, the number of lower word lines through which the lower channel LCH passes may be equal to or greater than the number of upper word lines through which the upper channel UCH passes. In addition, the structure and connection relationship of the channel structure CH arranged in the first cell region CELL1 as described above may be equally applied to the channel structure CH arranged in the second cell region CELL2.

In the bit line bonding region BLBA, a first through electrode THV1 may be provided in the first cell region CELL1 and a second through electrode THV2 may be provided in the second cell region CELL2. As shown in FIG. 13, the first through electrode THV1 may pass through the common source line 320 and the plurality of word lines 330. However, this is an example, and the first through electrode THV1 may further pass through the second substrate 310. The first through electrode THV1 may include a conductive material. In some implementations, the first through electrode THV1 may include a conductive material surrounded by an insulating material. The second through electrode THV2 may also be provided to have the same shape and structure as the first through electrode THV1.

In some implementations, the first through electrode THV1 and the second through electrode THV2 may be electrically connected to each other through a first through metal pattern 372d and a second through metal pattern 472d. The first through metal pattern 372d may be formed at a lower end of the first upper chip including the first cell region CELL1, and the second through metal pattern 472d may be formed at an upper end of the second upper chip including the second cell region CELL2. The first through electrode THV1 may be electrically connected to the first metal wiring 350c and the second metal wiring 360c. A lower via 371d may be formed between the first through electrode THV1 and the first through metal pattern 372d, and an upper via 471d may be formed between the second through electrode THV2 and the second through metal pattern 472d. The first through metal pattern 372d and the second through metal pattern 472d may be connected to each other by a bonding method.

In addition, in the bit line bonding region BLBA, an upper metal pattern 252 may be formed on the uppermost metal layer of the peripheral circuit region PERI, and an upper metal pattern 392 having the same shape as the upper metal pattern 252 may be formed on the uppermost metal layer of the first cell region CELL1. The upper metal pattern 392 of the first cell region CELL1 and the upper metal pattern 252 of the peripheral circuit region PERI may be electrically connected to each other by a bonding method. In the bit line bonding region BLBA, the bit line 360c may be electrically connected to a page buffer included in the peripheral circuit region PERI. For example, some of the circuit elements 220c of the peripheral circuit region PERI may provide a page buffer, and the bit line 360c may be electrically connected to the circuit elements 220c providing the page buffer, through an upper bonding metal 370c of the first cell region CELL1 and an upper bonding metal 270c of the peripheral circuit region PERI.

Subsequently, referring to FIG. 13, in the word line bonding region WLBA, the word lines 330 of the first cell region CELL1 may extend in a second direction (an X-axis direction) parallel to the upper surface of the second substrate 310 and may be connected to a plurality of cell contact plugs 341 to 347 (340). A first metal wiring 350b and a second metal wiring 360b may be sequentially connected to upper portions of the cell contact plugs 340 connected to the word lines 330. The cell contact plugs 340 may be connected to the peripheral circuit region PERI through an upper bonding metal 370b of the first cell region CELL1 and an upper bonding metal 270b of the peripheral circuit region PERI, in the word line bonding region WLBA.

The cell contact plugs 340 may be electrically connected to a row decoder included in the peripheral circuit region PERI. For example, some of the circuit elements 220b of the peripheral circuit region PERI may provide a row decoder, and the cell contact plugs 340 may be electrically connected to the circuit elements 220b providing the row decoder, through the upper bonding metal 370b of the first cell region CELL1 and the upper bonding metal 270b of the peripheral circuit region PERI. In some implementations, an operating voltage of the circuit elements 220b providing the row decoder may differ from an operating voltage of the circuit elements 220c providing the page buffer. For example, the operating voltage of circuit elements 220c providing the page buffer may be greater than the operating voltage of the circuit elements 220b providing the row decoder.

Similarly, in the word line bonding region WLBA, the word lines 430 of the second cell region CELL2 may extend in the second direction (the X-axis direction) parallel to the upper surface of the third substrate 410 and may be connected to a plurality of cell contact plugs 441 to 447 (440). The cell contact plugs 440 may be connected to the peripheral circuit region PERI through an upper metal pattern of the second cell region CELL2, lower and upper metal patterns of the first cell region CELL1, and a cell contact plug 348.

In the word line bonding region WLBA, the upper bonding metal 370b may be formed in the first cell region CELL1, and the upper bonding metal 270b may be formed in the peripheral circuit region PERI. The upper bonding metal 370b of the first cell region CELL1 and the upper bonding metal 270b of the peripheral circuit region PERI may be electrically connected to each other by a bonding method. The upper bonding metal 370b and the upper bonding metal 270b may include aluminum, copper, or tungsten.

In the external pad bonding region PA, a lower metal pattern 371c may be formed in a lower portion of the first cell region CELL1 and an upper metal pattern 472a may be formed in an upper portion of the second cell region CELL2. The lower metal pattern 371e of the first cell region CELL1 and the upper metal pattern 472a of the second cell region CELL2 may be connected to each other by a bonding method in the external pad bonding region PA. Likewise, an upper metal pattern 372a may be formed in upper portion of the first cell region CELL1, and an upper metal pattern 272a may be formed in an upper portion of the peripheral circuit region PERI. The upper metal pattern 372a of the first cell region CELL1 and the upper metal pattern 272a of the peripheral circuit region PERI may be connected to each other by a bonding method.

Common source line contact plugs 380 and 480 may be arranged in the external pad bonding region PA. The common source line contact plugs 380 and 480 may include a conductive material, such as a metal, a metal compound, or doped polysilicon. The common source line contact plug 380 of the first cell region CELL1 may be electrically connected to the common source line 320, and the common source line contact plug 480 of the second cell region CELL2 may be electrically connected to the common source line 420. A first metal wiring 350a and a second metal wiring 360a may be sequentially stacked on the common source line contact plug 380 of the first cell region CELL1, and a first metal wiring 450a and a second metal wiring 460a may be sequentially stacked on the common source line contact plug 480 of the second cell region CELL2.

First to third input/output pads 205, 405, and 406 may be arranged in the external pad bonding region PA. In FIG. 13, a lower insulating layer 201 may cover a lower surface of the first substrate 210, and the first input/output pad 205 may be formed on the lower insulating layer 201. The first input/output pad 205 may be connected to at least one of the circuit elements 220a arranged in the peripheral circuit region PERI, through a first input/output contact plug 203, and may be separated from the first substrate 210 by the lower insulating layer 201. In addition, a side insulating layer may be arranged between the first input/output contact plug 203 and the first substrate 210 to electrically separate the first input/output contact plug 203 from the first substrate 210.

An upper insulating layer 401 covering the upper surface of the third substrate 410 may be formed on the third substrate 410. The second input/output pad 405 and/or the third input/output pad 406 may be arranged on the upper insulating layer 401. The second input/output pad 405 may be connected to at least one of the circuit elements 220a arranged in the peripheral circuit region PERI, through second input/output contact plugs 403 and 303, and the third input/output pad 406 may be connected to at least one of the circuit elements 220a arranged in the peripheral circuit region PERI, through third input/output contact plugs 404 and 304.

In some implementations, the third substrate 410 may not be arranged in a region in which an input/output contact plug is arranged. For example, as shown in B, the third input/output contact plug 404 may be separated from the third substrate 410 in a direction parallel to the upper surface of the third substrate 410 and may be connected to the third input/output pad 406 through an interlayer insulating layer 415 of the second cell region CELL2. In this case, the third input/output contact plug 404 may be formed through various processes.

For example, as shown in B1, the third input/output contact plug 404 may extend in a third direction (a Z-axis direction) and may be formed to have a diameter that increases toward the upper insulating layer 401. That is, the diameter of the channel structure CH described in A1 may be formed to decrease toward the upper insulating layer 401, whereas the diameter of the third input/output contact plug 404 may be formed to increase toward the upper insulating layer 401. For example, the third input/output contact plug 404 may be formed after the second cell region CELL2 and the first cell region CELL1 are coupled to each other by a bonding method.

In addition, for example, as shown in B2, the third input/output contact plug 404 may extend in the third direction (the Z-axis direction) and may be formed to have a diameter that decreases toward the upper insulating layer 401. That is, like the channel structure CH, the diameter of the third input/output contact plug 404 may be formed to decrease toward the upper insulating layer 401. For example, the third input/output contact plug 404 may be formed together with the cell contact plugs 440 before the second cell region CELL2 and the first cell region CELL1 are bonded together.

In some implementations, an input/output contact plug may be arranged to overlap the third substrate 410. For example, as shown in C1-C3, the second input/output contact plug 403 may be formed to pass through the interlayer insulating layer 415 of the second cell region CELL2 in the third direction (the Z-axis direction) and may be electrically connected to the second input/output pad 405 through the third substrate 410. In this case, a connection structure between the second input/output contact plug 403 and the second input/output pad 405 may be implemented in various manners.

For example, as shown in C1, an opening 408 passing through the third substrate 410 may be formed, and the second input/output contact plug 403 may be directly connected to the second input/output pad 405 through the opening 408 formed in the third substrate 410. In this case, as shown in C1, the diameter of the second input/output contact plug 403 may be formed to increase toward the second input/output pad 405. However, this is an example, and the diameter of the second input/output contact plug 403 may be formed to decrease toward the second input/output pad 405.

For example, as shown in C2, the opening 408 passing through the third substrate 410 may be formed, and a contact 407 may be formed in the opening 408. One end of the contact 407 may be connected to the second input/output pad 405, and the other end of the contact 407 may be connected to the second input/output contact plug 403. Accordingly, the second input/output contact plug 403 may be electrically connected to the second input/output pad 405 through the contact 407 in the opening 408. In this case, as shown in C2, the diameter of the contact 407 may be formed to increase toward the second input/output pad 405, and the diameter of the second input/output contact plug 403 may be formed to decrease toward the second input/output pad 405. For example, the second input/output contact plug 403 may be formed together with the cell contact plugs 440 before the second cell region CELL2 and the first cell region CELL1 are bonded together, and the contact 407 may be formed after the second cell region CELL2 and the first cell region CELL1 are bonded together.

In addition, for example, as shown in C3, compared to C2, a stopper 409 may be further formed on an upper surface of the opening 408 of the third substrate 410. The stopper 409 may be a metal wiring formed on the same layer as the common source line 420. However, this is an example, and the stopper 409 may be a metal wiring formed on the same layer as at least one of the word lines 430. The second input/output contact plug 403 may be electrically connected to the second input/output pad 405 through the contact 407 and the stopper 409.

Similar to the second and third input/output contact plugs 403 and 404 of the second cell region CELL2, each of the second and third input/output contact plugs 303 and 304 of the first cell region CELL1 may be formed to have a diameter that decreases toward the lower metal pattern 37l or increases toward the lower metal pattern 371e.

According to some implementations, a slit 411 may be formed in the third substrate 410. For example, the slit 411 may be formed at an arbitrary position of the external pad bonding region PA. For example, as shown in D1-D3, in a plan view, the slit 411 may be positioned between the second input/output pad 405 and the cell contact plugs 440. However, this is an example, and in a plan view, the slit 411 may be formed such that the second input/output pad 405 is positioned between the slit 411 and the cell contact plugs 440.

For example, as shown in D1, the slit 411 may be formed to pass through the third substrate 410. The slit 411 may be used, for example, to prevent the third substrate 410 from being finely cracked when the opening 408 is formed. However, this is an example, and the slit 411 may be formed to have a depth of about 60% to about 70% of the thickness of the third substrate 410.

In addition, for example, as shown in D2, a conductive material 412 may be formed in the slit 411. The conductive material 412 may be used, for example, to discharge leakage current generated during driving of circuit elements in the external pad bonding region PA to the outside. In this case, the conductive material 412 may be connected to an external ground line.

In addition, for example, as shown in D3, an insulating material 413 may be formed in the slit 411. The insulating material 413 may be formed, for example, to electrically separate the second input/output pad 405 and the second input/output contact plug 403, which are arranged in the external pad bonding region PA, from the word line bonding region WLBA. By forming the insulating material 413 in the slit 411, a voltage provided through the second input/output pad 405 may be blocked from affecting a metal layer arranged on the third substrate 410 in the word line bonding region WLBA.

According to some implementations, the first to third input/output pads 205, 405, and 406 may be selectively formed. For example, the memory device 500 may be implemented to include only the first input/output pad 205 arranged on the first substrate 210, include only the second input/output pad 405 arranged on the third substrate 410, or include only the third input/output pad 406 arranged on the upper insulating layer 401.

According to some implementations, at least one of the second substrate 310 of the first cell region CELL1 and the third substrate 410 of the second cell region CELL2 may be used as a sacrificial substrate and may be completely or partially removed before or after a bonding process. Additional layers may be stacked after the substrate is removed. For example, the second substrate 310 of the first cell region CELL1 may be removed before or after bonding of the peripheral circuit region PERI and the first cell region CELL1, and an insulating layer covering an upper surface of the common source line 320 or a conductive layer for connection may be formed. Similarly, the third substrate 410 of the second cell region CELL2 may be removed before or after bonding of the first cell region CELL1 and the second cell region CELL2, and the upper insulating layer 401 covering an upper surface of the common source line 420 or a conductive layer for connection may be formed.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

1. A memory system including a storage controller for transmitting a read command to a memory device including a plurality of planes, the memory system comprising:
a command generation circuit configured to generate a first read command signal including an address signal set for each of the plurality of planes or a second read command signal including an address signal applied collectively to the plurality of planes;
a command selection circuit configured to determine either the first read command signal or the second read command signal as the read command; and
a memory controller configured to transmit the determined read command to the memory device,
wherein the command generation circuit is configured to generate the first read command signal based on read levels for correction of the plurality of planes being different from each other.

2. The memory system of claim 1, wherein the command generation circuit is configured to generate the second read command signal based on a read level of a first plane among the plurality of planes.

3. The memory system of claim 1, wherein the command generation circuit is configured to generate a first address signal based on a read level of a first plane among the plurality of planes and generate a second address signal based on a read level of a second plane among the plurality of planes.

4. The memory system of claim 3, wherein the command generation circuit is configured to generate the first read command signal including the first address signal and the second address signal.

5. The memory system of claim 1, comprising an analysis circuit configured to determine whether a deviation in read levels of the plurality of planes is equal to or greater than a preset standard.

6. The memory system of claim 5, wherein the command selection circuit is configured to, based on determining, as a result of the determination of the analysis circuit, that the deviation in the read levels of the plurality of planes is equal to or greater than the preset standard, determine the first read command signal as the read command.

7. The memory system of claim 1, comprising a buffer memory configured to store read levels of the plurality of planes.

8. An operating method of a memory system for generating a read command for a memory device including a plurality of planes, the operating method comprising:
determining a deviation in read levels of the plurality of planes;
determining, based on a result of the determining, either a first read command signal or a second read command signal as the read command; and
transmitting the read command to the memory device,
wherein determining the read command comprises generating the first read command signal based on read levels for correction of the plurality of planes being different from each other.

9. The operating method of claim 8, wherein the determining of the read command comprises generating the second read command signal based on a read level of a first plane among the plurality of planes.

10. The operating method of claim 8, wherein the determining of the read command comprises generating a first address signal based on a read level of a first plane among the plurality of planes and generating a second address signal based on a read level of a second plane among the plurality of planes.

11. The operating method of claim 10, wherein the determining of the read command comprises generating the first read command signal including the first address signal and the second address signal.

12. The operating method of claim 8, comprising determining whether the deviation in the read levels of the plurality of planes is equal to or greater than a preset standard.

13. The operating method of claim 12, wherein the determining of the read command comprises: based on determining, as a result of the determining, that the deviation in the read levels of the plurality of planes is equal to or greater than the preset standard, determining the first read command signal as the read command.

14. The operating method of claim 8, comprising storing the read levels of the plurality of planes.

15. A storage controller of a memory system for transmitting a read command to a memory device including a plurality of planes, the storage controller comprising:
a command generation circuit configured to generate a first read command signal including an address signal set for each of the plurality of planes or a second read command signal including an address signal applied collectively to the plurality of planes;
a command selection circuit configured to determine either the first read command signal or the second read command signal as the read command; and
a memory controller configured to transmit the determined read command to the memory device,
wherein the command generation circuit is configured to generate the first read command signal when read levels for correction of the plurality of planes are different from each other.

16. The storage controller of claim 15, wherein the command generation circuit is configured to generate the second read command signal based on a read level of a first plane among the plurality of planes.

17. The storage controller of claim 15, wherein the command generation circuit is configured to generate a first address signal based on a read level of a first plane among the plurality of planes and generate a second address signal based on a read level of a second plane among the plurality of planes.

18. The storage controller of claim 17, wherein the command generation circuit is configured to generate the first read command signal including the first address signal and the second address signal.

19. The storage controller of claim 15, further comprising an analysis circuit configured to determine whether a deviation in read levels of the plurality of planes is equal to or greater than a preset standard.

20. The storage controller of claim 19, wherein the command selection circuit is configured to: based on determining, as a result of the determination of the analysis circuit, that the deviation in the read levels of the plurality of planes is equal to or greater than the preset standard, determine the first read command signal as the read command.

21. (canceled)
